(19) United States
(12) Patent Application Publication
(10) Pub. No.: US 2024/0429216 A1
(43) Pub. Date: Dec. 26, 2024

(54) EMBEDDED INDUCTOR MODULE AND PACKAGED SEMICONDUCTOR DEVICE

(71) Applicant: TEXAS INSTRUMENTS INCORPORATED, DALLAS, TX (US)

(72) Inventors: Jie CHEN, PLANO, TX (US); Rajen MURUGAN, DALLAS, TX (US); Sylvester ANKAMAH-KUSI, MCKINNEY, TX (US); Harshpreet Singh Phull BAKSHI, DALLAS, TX (US); Jonathan NOQUIL, PLANO, TX (US)

(21) Appl. No.: 18/650,795

(22) Filed: Apr. 30, 2024

Related U.S. Application Data
(60) Provisional application No. 63/509,131, filed on Jun. 20, 2023.

(51) Int. Cl. H01L 25/16; H01L 21/48; H01L 23/00; H01L 23/13; H01L 23/498

(52) U.S. Cl. CPC H01L 25/16; H01L 21/4857; H01L 23/13; H01L 23/49822; H01L 23/49838; H01L 24/16; H01L 28/10; H01L 23/49894; H01L 2224/16225

(57) ABSTRACT

An example method includes forming a cavity in a multi-layer substrate of a leadframe. The cavity extends from a first substrate surface of the leadframe into the multi-layer substrate to define a cavity floor spaced from the first substrate surface by a cavity sidewall, and at least one conductive terminal is on the cavity floor. The method also includes placing an inductor module in the cavity, in which the inductor module includes a conductor embedded within a dielectric substrate between spaced apart first and second inductor terminals of the inductor module. The method also includes coupling at least one of the first and second inductor terminals to the at least one conductive terminal on the cavity floor. The method also includes encapsulating the inductor module and at least a portion of the leadframe with a mold compound.

### CROSS-REFERENCE TO RELATED APPLICATION

This application claims priority to U.S. provisional patent application No. 63/509,131, filed Jun. 20, 2023, which is incorporated herein by reference in its entirety.

### TECHNICAL FIELD

This description relates generally to an embedded inductor module and to a packaged semiconductor device, which can include an embedded inductor module.

### BACKGROUND

Inductors are used in a variety of electrical circuits, including power converter circuits. Electrical circuits are often fabricated in the form of an integrated circuit (IC). Integrating an inductor into an IC package with a die that includes the IC has proven to be problematic due to the relatively large size of inductors and other issues. For example, an on-wafer integrated inductor may have limited current handling ability due to a relatively high resistance associated with the inductor. Existing on-chip inductors also tend to have an insufficient quality factor (or Q), which can reduce performance of associated circuitry of the IC. A package level integration of a semiconductor device with a discrete inductor or magnetic core block further may be expensive and/or require a relatively complex assembly process.

### SUMMARY

One example described herein relates to a package apparatus that includes a multi-layer substrate and inductor module. The multi-layer substrate includes multiple substrate layers between first and second opposing surfaces and electrical traces on or within at least one of the multiple substrate layers. A cavity extends from the first surface through at least one of the substrate layers into the multi-layer substrate to define a cavity floor and cavity sidewalls extending from the cavity floor along at least one of the substrate layers to the first surface. At least one conductive terminal is exposed on the cavity floor. An arrangement of terminals on the first surface of the multi-layer substrate are spaced laterally from the cavity, and at least one of the terminals is coupled to at least one of the respective electrical traces. The inductor module includes a conductor embedded within a dielectric substrate and having inductor terminals. The inductor module includes first and second opposing surfaces spaced apart from each other by a side edge thereof. The second surface of the inductor module sits on the cavity floor with the side edge of the inductor module extending from the second surface to terminate at the first surface thereof. At least one of the inductor terminals is coupled to the at least one conductive terminal on the cavity floor. A mold compound encapsulates the inductor module and at least a portion of the multi-layer substrate.

Another example described herein relates to an inductor apparatus. The inductor apparatus includes a first winding of a conductive material having a radially inner periphery and a second winding of the conductive material spaced axially from and coupled to the first winding. The second winding has a radially inner periphery that is substantially coaxial with the radially inner periphery of the first winding to define a central region therein extending through and surrounded by the first and second windings. A central core of a magnetic mold compound is within at least a portion of the central region, and a dielectric material encapsulates the first and second windings and the central core.

Another example described herein relates to a method. The method includes forming a cavity in a multi-layer substrate of a leadframe. The cavity extends from a first substrate surface of the leadframe into the multi-layer substrate to define a cavity floor spaced from the first substrate surface by a cavity sidewall, and at least one conductive terminal is on the cavity floor. The method also includes placing an inductor module in the cavity, in which the inductor module includes a conductor embedded within a dielectric substrate between spaced apart first and second inductor terminals of the inductor module. The method also includes coupling at least one of the first and second inductor terminals to the at least one conductive terminal on the cavity floor. The method also includes encapsulating the inductor module and at least a portion of the leadframe with a mold compound.

### BRIEF DESCRIPTION OF THE DRAWINGS

FIG. 1 is a flow diagram illustrating an example method of forming a packaged semiconductor device.

FIGS. 2-6 are diagrams showing an example packaged semiconductor device at various stages of the method shown in FIG. 1.

FIG. 7 is an isometric view of an example inductor winding.

FIGS. 8 and 9 are side sectional views at different stages of making an example inductor module.

FIG. 10 is a side sectional view of an example inductor module.

FIG. 11 is a side sectional view of another example inductor module.

FIG. 12 is a side sectional view of another example inductor module.

FIGS. 13A, 13B, 13C, 13D are plan views showing different layers of an example multi-layer leadframe.

FIG. 14 is a plan view of an example leadframe that includes a cavity adapted to receive an inductor module.

FIG. 15 is a plan view of an example assembly illustrating an inductor module to the leadframe of FIG. 14.

### DETAILED DESCRIPTION

This description relates generally to embedded inductor modules and packaged semiconductor devices that include inductor modules.

As an example, an embedded inductor module includes a plurality of layers, in which respective windings are in different layers. In some examples, a high magnetic permeability material (e.g., having a relative magnetic permeability greater than approximately 10) can encapsulate the windings. Also, or as an alternative example, the windings can be planar spiral windings that are axially spaced apart and arranged to surround a central core, which can include a high magnetic permeability material (e.g., a magnetic mold compound).

In some examples, a packaged semiconductor device, such as an integrated circuit (IC) or system on chip (SOC), can include the inductor module. As an example, the inductor module is mounted on a cavity floor of a cavity that is formed in a multi-layer substrate (e.g., a multi-layer leadframe). The cavity floor can be a planar surface extending through one of the layers of the substrate that is adapted to receive the inductor module therein, and includes one or more terminals on the cavity floor. The inductor module has opposing surfaces and includes one or more terminals on one of its surfaces arranged and configured to contact respective terminal(s) on the cavity floor responsive to being placed on the cavity floor. The inductor module and substrate can be encapsulated in a mold compound to provide a packaged semiconductor device, such as described herein.

The inductor module enables increased inductance and lower resistance, which can achieve a higher Q than many existing inductors. Accordingly, the inductor module and packaged semiconductor device incorporating the inductor module can be used in power applications (e.g., power converters) with improved performance compared to many existing solutions.

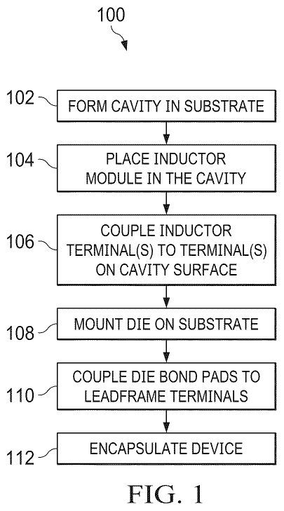

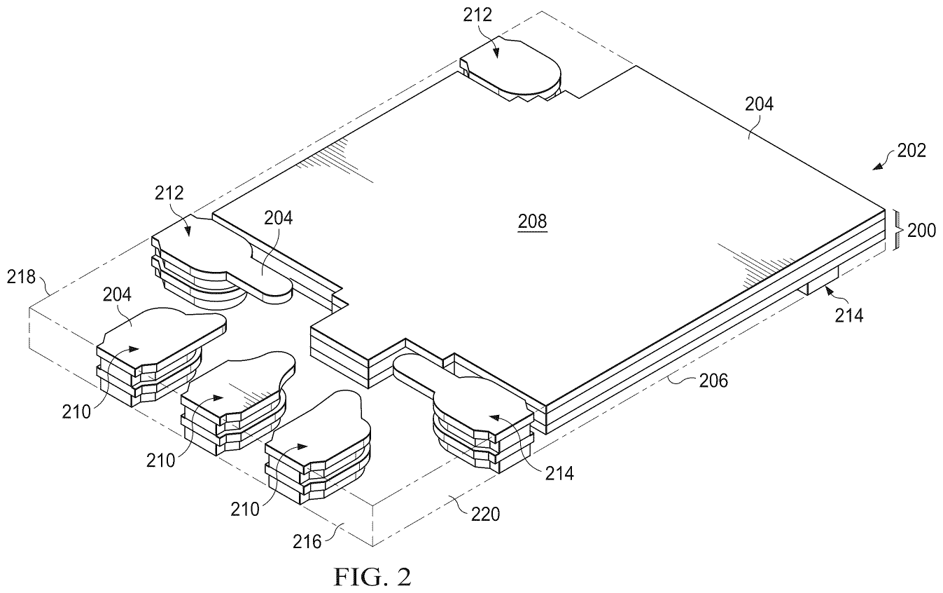

FIG. 1 is a flow diagram illustrating an example method 100 of forming a packaged semiconductor device. The method 100 is further described with respect to the device at various stages of the method, as illustrated in the examples of FIGS. 2-6. For example, the method 100 begins with a multi-layer substrate 200 being provided. The multi-layer substrate 200 can be configured as a leadframe 202 that includes multiple substrate layers between opposing surfaces 204 and 206. The leadframe 202 can be fabricated according to a multi-layer substrate fabrication technology, such as a routable lead frame (RLF) or embedded trace substrate (ETS) process, among others.

For example, an RLF is a multilayer package substrate that includes a plurality (at least two) of stacked layers, in which each layer is pre-configured with metal plating such as copper plating or interconnects to provide electrical connections in the package. An RLF package substrate is generally constructed by forming a dielectric layer such as a mold compound (generally comprising an epoxy material) or other organic compound(s) around a leadframe substrate comprising a metal material between a patterned top metal layer and a patterned metal bottom layer. Such package substrates can comprise single- or multi-die configurations, both lateral and vertically stacked, which can include dielectric and/or metal layers (e.g., patterned metal) and include a number of vias extending between or through two or more of the layers.

As a further example, an ETS is a multilayer package substrate that includes trace conductor layers that are spaced by prepreg laminated layers. The prepreg layers are dielectric material. Vias (e.g., conductive vias) are formed through the prepreg layers between multiple layers of trace conductors and couple the trace conductor layers. Additionally, the ETS can be used as a package substrate with multiple trace layers, and one or more passive components mounted to the ETS. A mold compound can cover the ETS, a semiconductor die mounted to the ETS and a passive component. A recess can be opened extending into the ETS from a device side surface to expose trace conductors at a trace level beneath the device side surface, and the passive component is mounted in the recess in the ETS.

In the multi-layer substrate 200, a region 208 where an inductor module will be placed includes one or more layers of a metal material, such as copper. In some examples, the one or more metal layers in the region 208 are in the form a copper block having a thickness defined by the spacing between the surfaces 204 and 206 thereof, which can be commensurate with the thickness of the multi-layer substrate 200. Also, or as alternative, electrical traces can be formed on or within one or more layers of the multi-layer substrate 200 of the leadframe 202 for package routing, which can depend on application requirements. The leadframe 202 also includes an arrangement of terminals 210, 212 and 214 on the surface 204 of the multi-layer substrate 200 that are spaced laterally from the region 208 where the cavity is to be formed. The terminals 210 can be multi-layer terminals that can define and/or be coupled to respective ones of the electrical traces in the leadframe 202. In the example of FIG. 2, the terminals 210 are arranged along and extend outwardly from a respective side 216 of the leadframe 202. The terminals 212 are arranged along and extend outwardly from another respective side 218 of the leadframe 202, and the terminals 214 are arranged along and extend outwardly from yet another respective side 220 of the leadframe. Thus, the terminals 210, 212 and 214 extending from the leadframe are adapted to be coupled to pads of another IC or a printed circuit board.

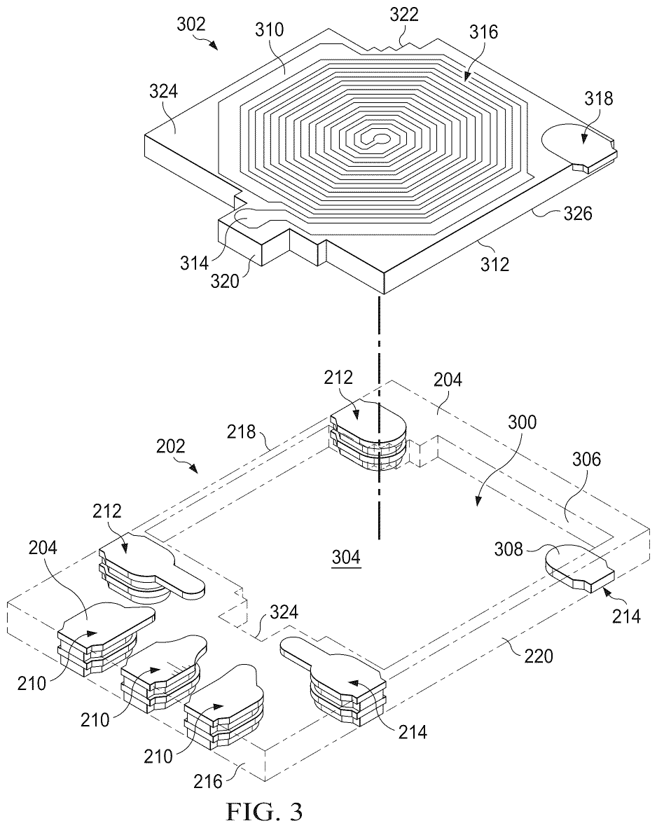

At 102, the method 100 includes forming a cavity in a multi-layer substrate of the leadframe. For example, FIG. 3 illustrates the leadframe 202 that includes a cavity 300 formed in the metal layer(s) 208 at the region where an inductor module 302 is to be placed. The cavity 300 can be formed by selectively removing a portion of the metal layer(s) 208 from the multi-layer substrate 200, such as by etching (e.g., laser etching, chemical etching or the like). The cavity 300 extends from the surface 204 into the multi-layer substrate 200 to define a cavity floor 304 spaced from the surface 204 by a cavity sidewall 306. Also, one or more conductive terminals 308 can be formed on the cavity floor responsive to the etching during cavity formation.

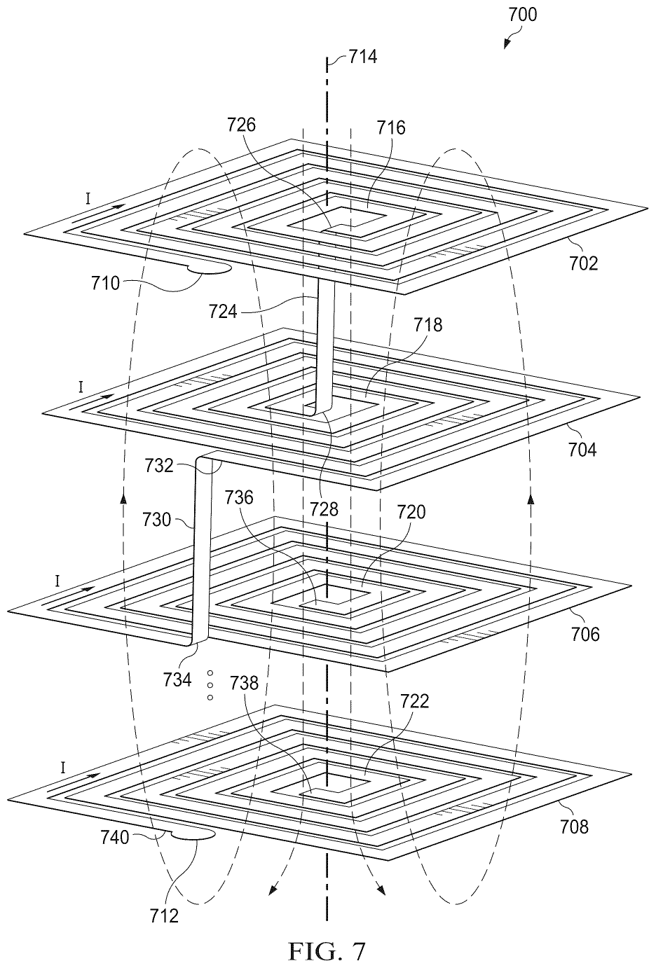

As shown in the example of FIG. 3, the inductor module 302 module includes a conductor 310 embedded within a dielectric substrate 312 between a first inductor terminal 314 and a second inductor terminal (not shown in FIG. 3) of the inductor module. The first inductor terminal 314 and the second inductor terminal are axially spaced apart from each other. In some examples, the inductor module 302 is formed as multiple layers, in which the conductor 310 of a first (e.g., top) layer defines a first planar winding 316, as shown in FIG. 3. The inductor module 302 thus can include any number of one or more layers between opposing surfaces 324 and 326 thereof. While the example winding 316 is shown as having a hexagonal shape, the windings of an inductor module can have other shapes, including circular, rectangular, or other polygonal shapes. One or more other layers of the conductor 310 can be formed as respective windings in other layers of the inductor module 302, in which the winding at each layer can be coupled to one or more windings of adjacent layers by respective coupling conductors (see, e.g., FIG. 7).

A layer of the inductor module 302 at the surface 326, which is opposite the layer containing the first winding 316 at the surface 324, can include the second inductor terminal that is coupled to another terminal 318 of the inductor module 302, such as through an electrically conductive via extending from the second inductor terminal to the terminal 318. In an example, the terminal 318, the first winding 316, and the inductor terminal 314 are coplanar, such as formed in a common layer of the conductor. As examples, the multi-layer inductor module 302 is fabricated according to a substrate fabrication technology, such as a routable lead frame (RLF) or an embedded trace substrate (ETS) package technology. When seen from a plan view (e.g., top view) of the assembly, which includes the inductor module 302 and the leadframe 202, the inductor module 302 has a perimeter that is dimensioned and configured to fit within the cavity sidewall 306. In the example of FIG. 3, the inductor module 302 includes a tab 320 extending outwardly from a central region of a respective side and a notch 322 formed in a corner thereof. The inductor terminal 314 can extend onto the tab 320. The cavity 304 is configured to receive the inductor module therein. For example, the cavity 304 includes a notch 322 that aligns with the tab 320, and the terminal 212 is aligned to fit in the notch 322 of the inductor module. Other relative sizes and/or configurations for the inductor module 302 and the cavity 304 can be used in other examples to enable the integrated assembly to be formed.

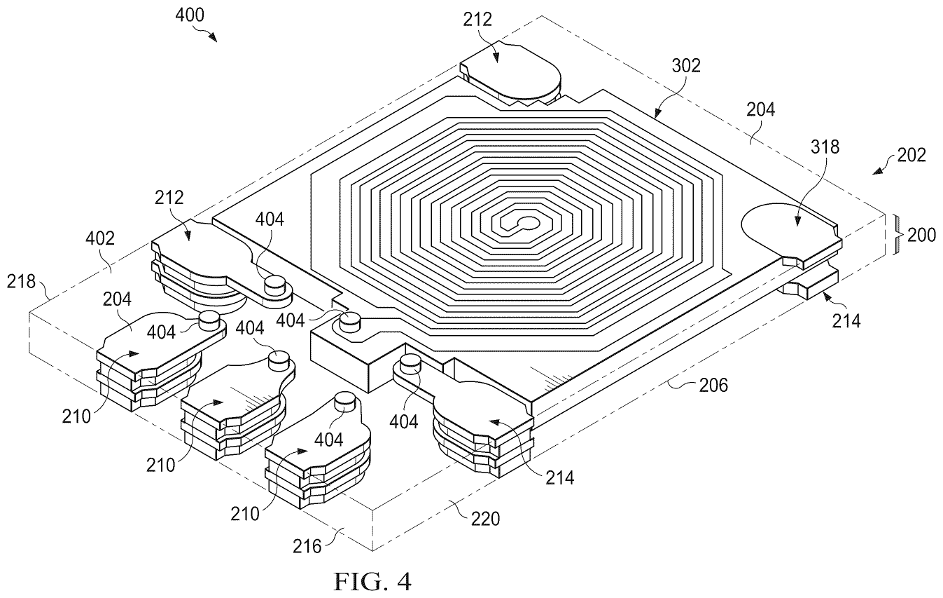

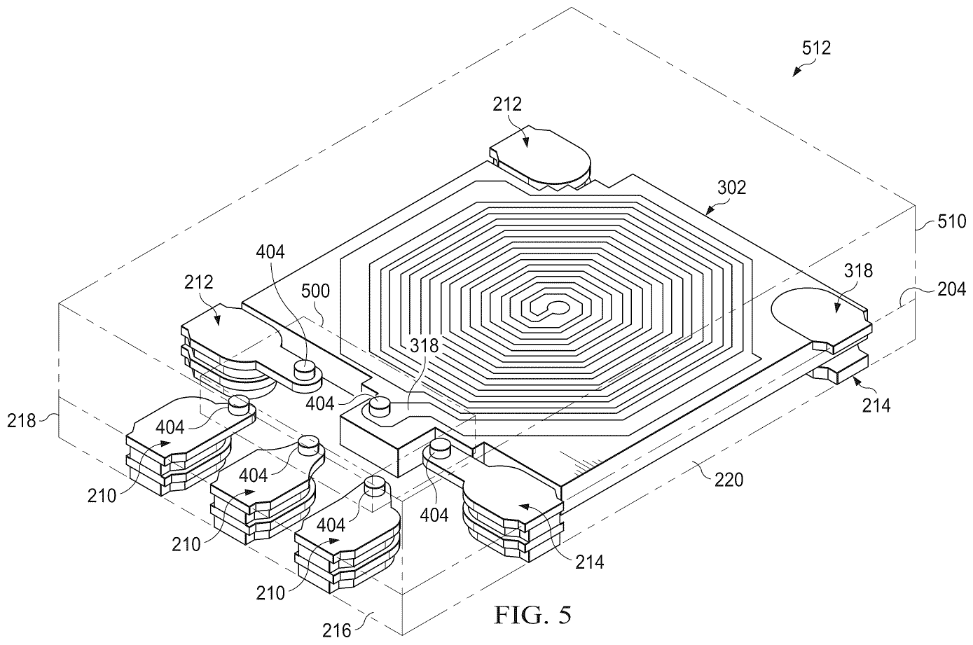

At 104, the method 100 includes placing the inductor module in the cavity. For example, FIG. 4 illustrates the inductor module 302 placed in the cavity 304 to form an integrated assembly 400. As shown in FIG. 4, the inductor module 302 is configured to fit securely within the cavity 304. In some examples, the surface 324 of the inductor module 302 is coplanar with the surface (e.g., the top surface) 204 of the leadframe 202, such as to enable mounting of another IC die to a surface 402 of the assembly 400. For example, an electrically conductive die attach material (DAM), such as solder, solder paste, or another conductive bonding agent, shown at 404, is formed on bond pads of respective conductive terminals at the surface 402 of the assembly. In the example of FIG. 4, the DAM 404 is formed (e.g., by plating or deposition) on the bond pads of the terminals 210, 212 and 214 of the leadframe 202 and on the inductor terminal 314. The bond pad locations are arranged and configured to be coupled to die pads of a die that is to be attached to the leadframe 202 (see, e.g., FIG. 5). In the example of FIG. 4, the bond pads and DAM 404 for the leadframe terminals 210, 212 and 214 are spaced inwardly from the sides 216, 218 and 220, respectively.

At 106, the method 100 includes coupling at least one inductor terminal to the at least one conductive terminal on the cavity floor. In the example of FIG. 4 the coupling (at 106) can be implemented by solder, solder paste, a conductive adhesive or by direct contact between the terminal 214 and the inductor terminal (located on the bottom side of the inductor module and coupled to the terminal 318).

At 108, the method 100 includes mounting a die to the leadframe and, at 110, the method includes coupling the bond pads to respective conductive leadframe terminals. The mounting and coupling at 108 and 112 can occur sequentially or concurrently, and further can depend on the type of packing process. For example, FIG. 5 shows a die 500 mounted to the surface 402 of the leadframe 202 overlying the DAM 404 that has been placed on the terminals 210, 212, 214 and 314. The pads of the die 500 can be coupled to the terminals through the DAM 404, can be implemented by solder, solder paste, a conductive adhesive or by direct contact between the die pads and the bond pads on the leadframe 202. For example, a solder or solder paste can be heated through a reflow process and then cooled to couple the die to the respective terminals of the leadframe 202. In some examples, the die 500 includes a power converter circuit having an output that is coupled to the inductor terminal 314. The terminal 318 thus is coupled to the other inductor terminal, which can be coupled to a capacitor and/or a load to which the power converter is to supply electrical power (e.g., voltage and current).

At 112, the method 100 includes encapsulating the inductor module and at least a portion of the leadframe with a mold compound. For example, FIG. 5 illustrates the die 500, inductor module 302 and the leadframe 202 encapsulated by a mold compound 510 to provide a packaged semiconductor device 512. The mold compound 510 can include one or more dielectric materials, such as an organic resin (e.g., epoxy), inorganic resins, and/or other suitable materials. In the example of FIG. 5, the packaged semiconductor device 512 thus includes the leadframe 202, inductor module 302 and die 500. In other examples, additional components, including more than one inductor module and/or more than one die, can be implemented in the packaged semiconductor device 512.

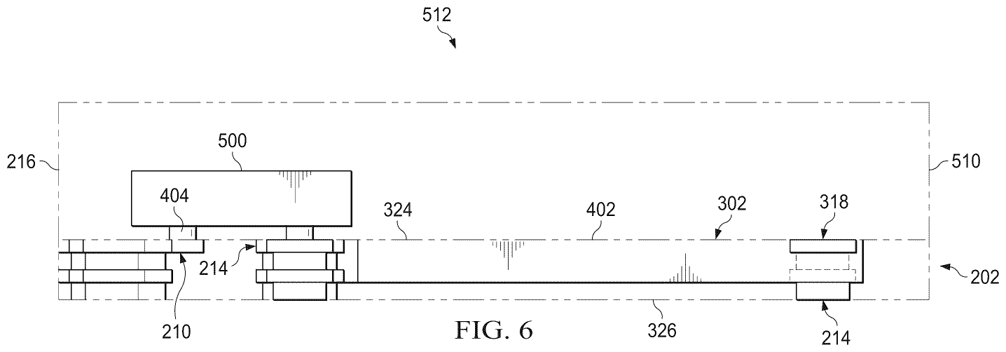

FIG. 6 illustrates a side view of the packaged semiconductor device 512 of FIG. 5. As shown in FIG. 6, the packaged semiconductor device includes the leadframe 202, the inductor module 302 and the die 500 mounted to both the leadframe and inductor module. The mold compound 510 encapsulates the die 500 and at least a portion of the inductor module 302 and leadframe 202. For example, contact portions of the terminals 210, 212 (not shown in FIG. 6, but see FIGS. 5) 214, and 318 can extend outwardly from the package, such as for coupling the device 512 to a substrate (e.g., a PCB or another die).

FIG. 7 illustrates an isometric view of an example inductor apparatus 700. The inductor apparatus 700 includes a plurality of windings 702, 704, 706, and 708 of a conductive material (e.g., copper, or other conductive material) extending between inductor terminals 710 and 712. The inductor apparatus 700 can include any number of two or more such windings 702, 704, 706, and 708, which can vary depending on application requirements and an intended use environment. In the example of FIG. 7, the windings 702 and 708 are at respective ends (e.g., top and bottom windings) of the inductor apparatus 700.

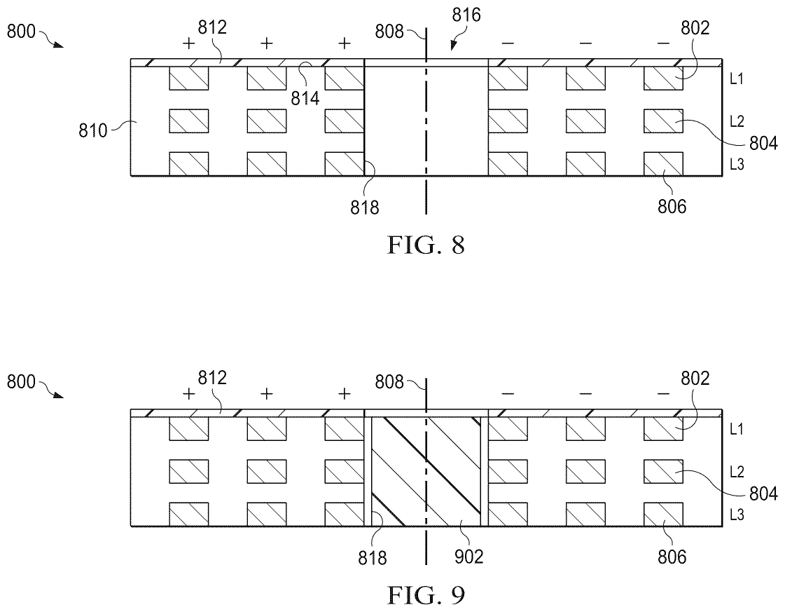

In an example, each of the windings 702, 704, 706, and 708 is a planar conductor formed by plating (e.g., electroplating) or deposition of the conductive material through a patterned mask in a respective layer. The windings 702, 704, 706, and 708 can be formed in the respective layers according to a substrate fabrication technology (e.g., RLF or ETS), such that each layer includes a conductor on or within a volume of an insulating dielectric material (e.g., a mold compound—not shown in FIG. 7—but see FIGS. 8-12). As described herein, the dielectric material can have a high relative permeability (e.g., μᵣ>10, such as μᵣ≈20 or more), such as an MMC or an embedded MMC (eMMC). Examples of MMC (and eMMC) materials that can be used to form inductors herein include ferromagnetic materials such as ferrite M33, nickel, ferrite N41, iron, ferrite T38, silicon GO steel, and supermalloy to list a few. These materials have sufficiently high relative permeabilities to make inductors having high Q. For example, ferrite M33 has a relative permeability of 750. Nickel has a relative permeability of 600. Ferrite N41 has a relative permeability of 2800. Ferrite T38 has a relative permeability of 10,000. Silicon GO steel has a relative permeability of 40,000. Supermalloy has a relative permeability of 1,000,000.

In the example of FIG. 7, each of the windings 702, 704, 706, and 708 has a planar rectangular spiral configuration that winds around a central axis 714 extending through the inductor apparatus 700. Other spiral shapes and non-spiral shapes can be implemented for the windings 702, 704, 706, and 708 in other examples. The configuration of the windings 702, 704, 706, and 708 at each layer of the inductor apparatus 700 can be the same or different, which can depend on the patterned mask used to form the winding at each layer. Each winding 702, 704, 706, 708 can include one or more turns around the central axis between respective ends thereof and be coextensive with the windings in other layers. Also, in some examples, each of the windings 702, 704, 706, and 708 has a radially inner edge 716, 718, 720, and 722, respectively. The radially inner edges 716, 718, 720, and 722 can surround a central region at each respective layer, which edges collectively can define a boundary for a central core region extending axially through the inductor apparatus 700. In some examples, the inductor apparatus 700 can include a central core of a magnetic (e.g., ferromagnetic or ferrimagnetic) material having a high relative magnetic permeability, such as iron, MMC, eMMC, silicon steel, ferrite, a nanocrystalline alloy, nickel, a composite material, or combinations and alloys thereof.

Each of the windings 702, 704, 706, and 708 can be coupled to one or more other windings by a length of the conductive material, which can be formed as conductive vias. In the example of FIG. 7, a conductive via 724 extends axially between radially inner ends 726 and 728 of the respective windings 702 and 704. Another conductive via 730 extends axially between radially outer ends 732 and 734 of the respective windings 704 and 706. The other windings of the inductor apparatus (if any) can be coupled together by similar vias extending between corresponding ends of the respective windings. For example, a radially inner end 736 of the winding 706 either defines an end terminal of the inductor apparatus or is coupled to a next winding. Similarly, depending on the number of windings, one of the ends 738 or 740 defines the end terminal 712 of the inductor apparatus and the other end is coupled to an adjacent winding by a conductive via (not shown). In the example of FIG. 7, the end 740 of the winding 708 is shown as the end 712 of the inductor apparatus.

FIGS. 8 and 9 are cross-sectional views illustrating another example inductor module 800. As an example, the inductor module 800 includes a multi-layer inductor that includes a plurality of windings 802, 804, and 806 of a conductive material (e.g., copper) at respective layers, shown as layers L1, L2, and L3. Other numbers of windings can be used in other examples. Each of the windings 802, 804, and 806 can be a planar winding formed in a respective layer L1, L2, and L3, such as described herein (e.g., in an RLF or other laminate substrate). Each winding 802, 804, and 806 can include a number of turns having a spiral or other configuration around a central axis 808. The windings are embedded in a substrate material 810, such as a dielectric substrate material. The substrate material 810 can be a build-up film such as Ajinomoto Build-up Film (ABF) dielectric materials, a prepreg material (e.g., a fiber weave or cloth of glass fibers, pre-impregnated with a bonding agent), or an epoxy material (e.g., a mold compound epoxy). For example, ABF is commercially available from Ajinomoto Co., Inc. and is known to comprise an epoxy resin together with a phenolic hardener. The windings 802, 804, and 806 can be coupled to each other through conductive vias (not shown) similar to as described with respect to FIG. 7. A solder mask layer 812 can be formed on a surface 814 of the inductor module 800.

In the example of FIG. 8, the inductor module 800 is shown at an intermediate stage of fabrication in which a central core of the dielectric material 810 has been removed (e.g., by etching or another method). For example, a central opening 816 can be formed in the solder mask 812 and through the dielectric material 810 around the central axis. A volume of the dielectric material 810 can be removed from the inductor module 800 to define a boundary 818 of a central core region extending axially through (e.g., partially or completely through) the inductor module. The boundary 818 can provide a cylindrical aperture through the inductor module at or spaced radially inwardly from an inner periphery (e.g., edge) of the respective windings 802, 804, and 806.

As shown in FIG. 9, the inductor module includes a central core 902 of material having a high magnetic permeability, such as MMC. For example, a molten MMC can be provided within the aperture (e.g., by placing the module in a mold chase) and then cooled to form the central core 902. In other examples, different magnetic materials can be used to form the central core 902. The solder mask layer 812 may be retained or, in some examples, the solder mask layer may be removed from the inductor module.

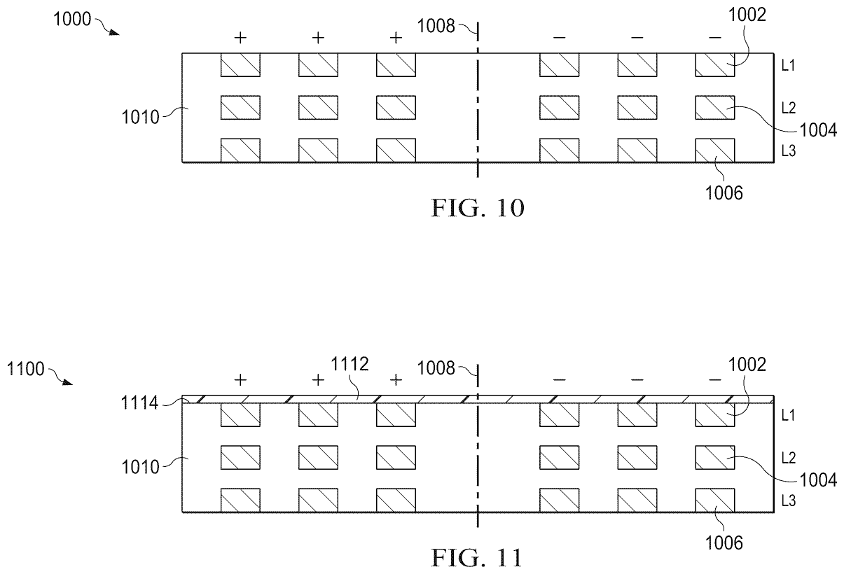

FIGS. 10-12 are cross-sectional views illustrating other example inductor modules 1000, 1100, and 1200. The inductor module 1000 of FIG. 10 is a multi-layer inductor that includes a plurality of windings 1002, 1004, and 1006 of a conductive material (e.g., copper) at respective layers L1, L2, and L3. Each of the windings 1002, 1004, and 1006 can be a planar winding formed around a central axis 1008 in a respective layer L1, L2, and L3, such as described herein. The windings 1002, 1004, and 1006 are embedded in a magnetic substrate material 1010, such as an MMC having a high magnetic permeability as described herein. The windings 1002, 1004, and 1006 can be coupled to each other through conductive vias (not shown) similar to as described with respect to FIG. 7 to provide an integrated multi-layer winding. By surrounding the windings 1002, 1004, and 1006 and conductive vias with MMC, the inductor module can exhibit an increased inductance compared to many existing integrated inductors. The inductor module 1000 can be formed according to a multi-layer substrate fabrication technology, such as an RLF or ETS process. The inductor module 1100 of FIG. 11 can be the same or identical to as described with respect to FIG. 10 and include a solder mask layer 1112 on a surface 1114 of the inductor module. The solder mask layer 1112 thus may be included or omitted from the inductor module depending on the substrate type and fabrication technology being used.

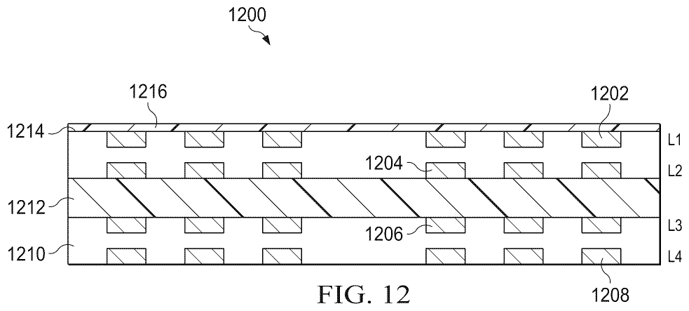

FIG. 12 depicts another inductor module 1200, which is a multi-layer inductor that includes a plurality of windings 1202, 1204, 1206, and 1208 of a conductive material (e.g., copper) in respective substrate layers L1, L2, L3, and L4. The respective layers L1, L2, L3, and L4 and the inductor module 1200 can be formed according to a multi-layer substrate fabrication technology, such as an RLF or ETS process. The windings 1202, 1204, and 1206 are embedded in a dielectric substrate material 1210, such as prepreg or ABF. In the example of FIG. 12, a layer 1212 of a material having a high magnetic permeability, such as an MMC, can be formed over the L3 layer. A solder mask layer 1214 can also be formed on a surface 1216 of the inductor module 1200. Alternatively, the solder mask layer 1214 can be omitted from the inductor module 1200, such as depending on the substrate type and fabrication technology being used. Each of the windings 1202, 1204, 1206, and 1208 can be a planar winding formed around a central axis 1210 in a respective one of the layer L1, L2, and L3, such as described herein. The windings 1202, 1204, and 1206 can be coupled to each other through conductive vias (not shown) similar to as described with respect to FIG. 7 to provide an integrated multi-layer winding. By providing the layer of MMC or other high magnetic permeability material between layers L2 and L3, the inductor module 1200 can exhibit an increased inductance compared to many existing integrated inductors.

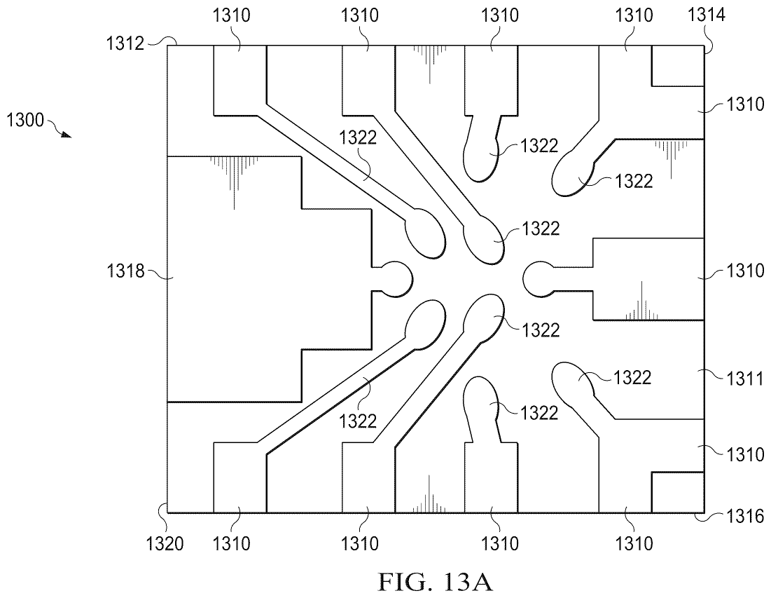

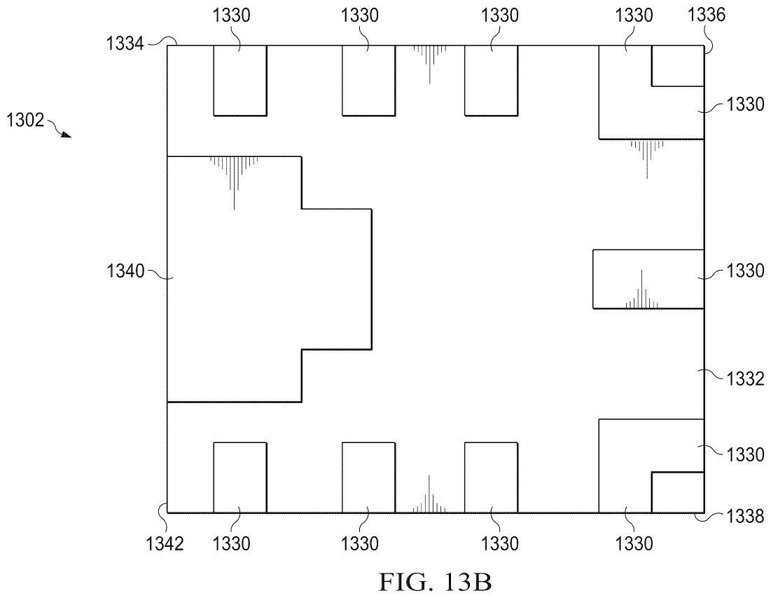

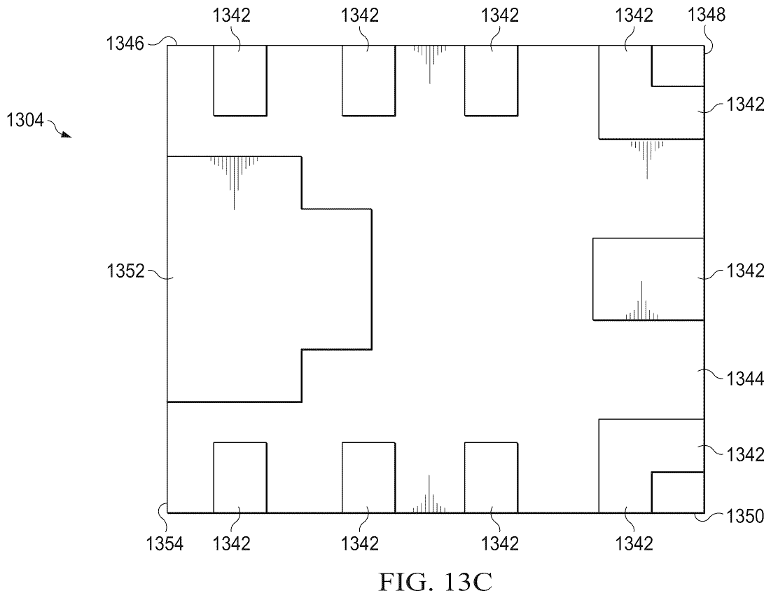

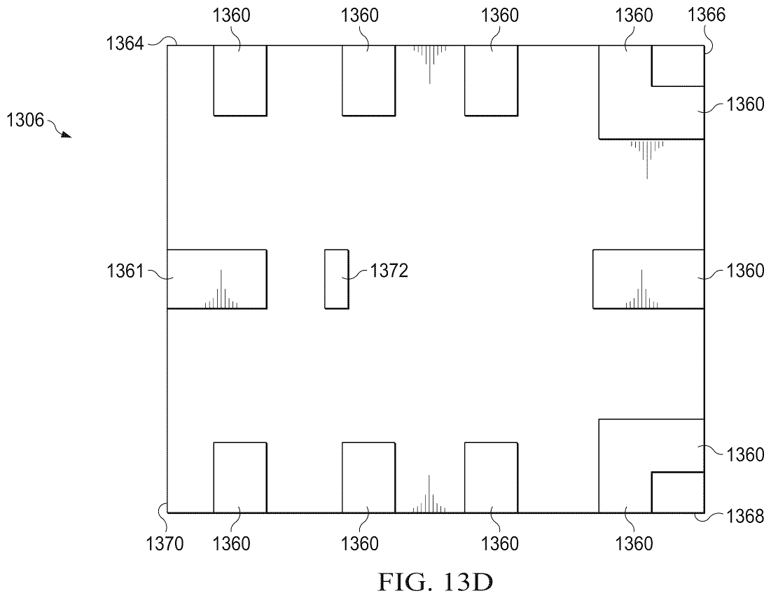

FIGS. 13A, 13B, 13C, 13D are plan views showing a surface (e.g., a top surface) of different layers (also referred to herein as leadframe layers) 1300, 1302, 1304, and 1306 of an example multi-layer leadframe. In an example, the layer 1300 is a top layer and the layer 1306 is a bottom layer of the leadframe. The layers 1302 and 1304 are intermediate layers of the leadframe. As shown in FIGS. 13A-13D, each leadframe layer 1300, 1302, 1304, 1306 includes an arrangement of patterned metal in a layer of a dielectric substrate. As described herein, the respective leadframe layers 1300, 1302, 1304, and 1306 can be fabricated consecutively according to a multi-layer substrate fabrication technology, such as a RLF or ETS process, to form the leadframe.

As shown in the example of FIG. 13A, the layer 1300 includes an arrangement of metal (e.g., copper) terminals 1310 formed in a layer of a dielectric substrate (e.g., ABF) 1311 along three adjacent side edges 1312, 1314, and 1316 of the leadframe layer. A block of a conductive metal (e.g., copper) 1318 is formed in the substrate 1311 along another side 1320 between terminals 1310 adjacent the side 1320. The layer 1300 also includes traces 1322 of metal (e.g., copper) extending inwardly from each of the terminals 1310 and the metal block 1318 to terminate in conductive pads near a central region of the leadframe layer.

The example layer 1302 of FIG. 13B includes an arrangement of metal (e.g., copper) terminals 1330 formed in a layer of a dielectric substrate (e.g., ABF) 1332 along three adjacent side edges 1334, 1336, and 1338 of the leadframe layer. The layer 1302 also includes a block of a conductive metal (e.g., copper) 1340 formed on the substrate 1332 along another side 1342 between terminals 1330 adjacent the side 1342. The terminals 1330 and metal block 1340 extend between opposing top and bottom surfaces of the layer 1302 and are arranged and configured to couple to the respective terminals 1310 and metal block 1318 of the adjacent (e.g., top) layer 1300.

As shown in FIG. 13C, the layer 1304 can be the same as the layer 1302 of FIG. 13B. The layer 1304 includes an arrangement of metal (e.g., copper) terminals 1342 formed in a layer of a dielectric substrate (e.g., ABF) 1344 along three adjacent side edges 1346, 1348, and 1350 of the leadframe layer. The layer 1304 also includes a block of a conductive metal (e.g., copper) 1352 formed in the substrate 1344 along another side 1354 between terminals 1342 adjacent the side 1354. The terminals 1342 and metal block 1352 are arranged and configured to couple to respective terminals 1330 and metal block 1340 of the adjacent intermediate layer 1302.

The leadframe layer 1306 shown in FIG. 13D includes an arrangement of metal (e.g., copper) terminals 1360 formed in a layer of a dielectric substrate (e.g., ABF) 1362 along each of the side edges 1364, 1366, and 1368, and a terminal 1361 along the side edge 1370 of the layer. The metal terminals 1360 and 1361 can provide connections adapted to couple to external circuitry, such as a PCB and/or a die. The layer 1306 also includes another metal terminal 1372 that is spaced apart inwardly from the terminal 1361 along the side edge 1370 and intermediate between side edges 1364 and 1368. The terminals 1360 are arranged and configured to couple to the respective terminals 1330 and metal block 1340 of the adjacent intermediate layer 1304. As described herein, the terminal 1361 along the side edge 1370 and the terminal 1372 are adapted to be coupled to respective terminals of an inductor module (e.g., inductor module 302, 800, 900, 1000, 1100, 1200, 1502).

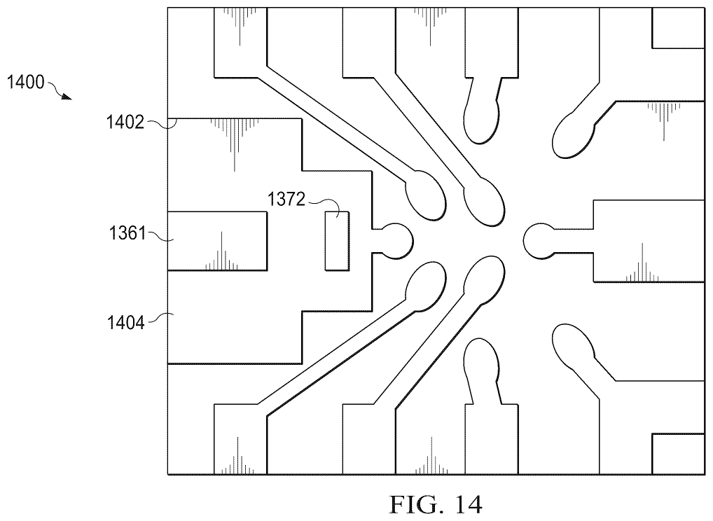

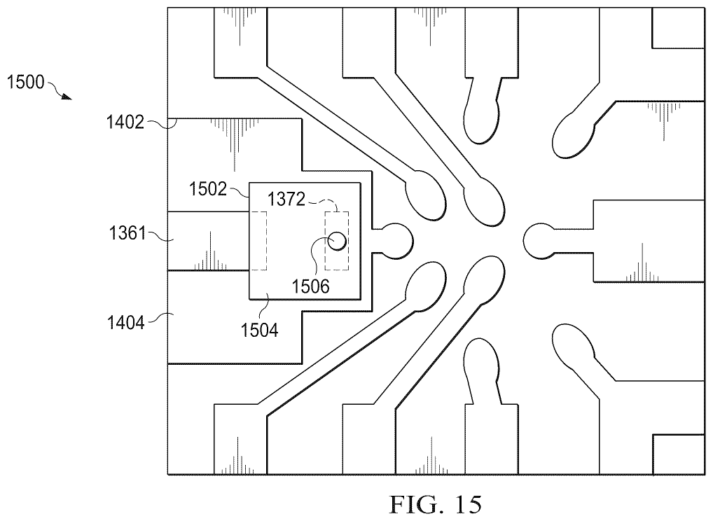

FIG. 14 is a plan view of a leadframe 1400, which can include the leadframe layers 1300, 1302, 1304, and 1306. In the example of FIG. 14, a portion of the layers, corresponding to metal blocks 1318, 1340 and 1352, have been removed (e.g., by etching) to form a cavity 1402 in the multi-layer leadframe 1400. The cavity 1402 has a cavity floor 1404, and terminals 1361 and 1372 (e.g., formed in layer 1306) are exposed on the cavity floor. As described herein, the terminal 1361 is also adapted to be coupled to an external device, such as a PCB or another IC.

FIG. 15 is a plan view of an assembly 1500, which includes the leadframe 1400 of FIG. 14 and an inductor module 1502 in the cavity 1402. The inductor module 1502 has opposing surfaces, in which a contact (e.g., bottom) surface includes terminals (not shown) arranged and configured to couple to the terminals 1361 and 1372 on the cavity floor 1404 of the leadframe. The inductor terminals on the contact surface of the inductor module 150 can be coupled to respective conductive terminals on the cavity floor 1404 (e.g., by a DAM, such as solder). The inductor module 1502 can be a multi-layer inductor (e.g., inductor module 302, 800, 900, 1000, 1100, 1200) having another surface (e.g., a top surface) 1504 that is spaced apart from the contact surface by one or more layers that include respective windings, such as described herein. The surface 1504 includes a conductive terminal 1506, which is coupled to an inductor terminal of the inductor module and adapted to be coupled to an output terminal of a die (e.g., die 500) containing active circuitry. The terminal 1506 on the surface 1504 can be coplanar with the conductive pads on the surface layer 1300.

In an example, the die includes a power converter (e.g., a switching power supply) and the output terminal thereof is coupled to terminal 1506 for coupling the power converter to the inductor. For example, the die includes die pads that can be coupled directly to conductive pads of the leadframe 1400 and to the terminal 1506 (e.g., coupled to an inductor terminal). In other examples, the die can be coupled to conductive pads of the leadframe 1400, at least one of which is coupled to the inductor terminal through respective traces of the leadframe, bond wires, or other types of electrical connections. The inductor module 1502, die and at least a portion of the leadframe 1400 can be encapsulated in a mold compound to provide a packaged semiconductor device, such as described herein.

In this description, the term “couple” or “couples” means either an indirect or direct connection. Thus, if a first device couples to a second device, that connection may be through a direct connection or through an indirect connection via other devices and connections. For example, if device A generates a signal to control device B to perform an action, then: (a) in a first example, device A is coupled to device B; or (b) in a second example, device A is coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A package apparatus comprising:
a multi-layer substrate having multiple substrate layers between first and second opposing surfaces, electrical traces on or within at least one of the multiple substrate layers, a cavity extending from the first surface through at least one of the substrate layers into the multi-layer substrate to define a cavity floor and cavity sidewalls extending from the cavity floor along the at least one of the substrate layers to the first surface, at least one conductive terminal exposed on the cavity floor, an arrangement of terminals on the first surface of the multi-layer substrate being spaced laterally from the cavity, and at least one of the terminals being coupled to at least one of the respective electrical traces;
an inductor module including a conductor embedded within a dielectric substrate and having inductor terminals, the inductor module having first and second opposing surfaces spaced apart from each other by a side edge thereof, the second surface of the inductor module sitting on the cavity floor with the side edge thereof extending from the second surface to terminate at the first surface of the inductor module, and at least one of the inductor terminals being coupled to the at least one conductive terminal on the cavity floor; and
a mold compound encapsulating the inductor module and at least a portion of the multi-layer substrate.

2. The package apparatus of claim 1, wherein the multi-layer substrate is a leadframe.

3. The package apparatus of claim 2, further comprising a die having bond pads, in which the die is mounted to the first surface of the leadframe, in which the bond pads are coupled to at least some of the terminals on the first surface of the leadframe, and the mold compound also encapsulates the die.

4. The package apparatus of claim 1, wherein the multi-layer substrate comprises multiple layers of an insulating buildup material.

5. The package apparatus of claim 1, wherein the dielectric substrate has a magnetic permeability that is greater than the mold compound.

6. The package apparatus of claim 5, wherein the mold compound is a non-magnetic mold compound and the dielectric substrate is a magnetic mold compound.

7. The package apparatus of claim 1, wherein the conductor of the inductor module is a multi-layer conductor comprising:
a first winding of a conductive material having a radially inner edge;
a second winding of the conductive material spaced axially from and overlying the first winding, in which the second winding is coupled to the first winding through the dielectric substrate, the second winding has a radially inner edge coaxial with the radially inner edge of the first winding to define a central region extending coaxially through the first and second windings, and the dielectric substrate encapsulates the first and second windings; and
a central core of a magnetic mold compound within at least a portion of the central region.

8. The package apparatus of claim 7, wherein each of the first and second windings has a spiral shape surrounding the central region.

9. An inductor apparatus, comprising:
a first winding of a conductive material having a radially inner periphery;
a second winding of the conductive material spaced axially from and coupled to the first winding, in which the second winding has a radially inner periphery that is substantially coaxial with the radially inner periphery of the first winding to define a central region therein extending through and surrounded by the first and second windings;
a central core of a magnetic mold compound within at least a portion of the central region; and
a dielectric material encapsulating the first and second windings and the central core.

10. The apparatus of claim 9, further comprising:
a conductive terminal on a surface of the dielectric material, the conductive terminal coupled to an end portion of one of the first and second windings.

11. The apparatus of claim 10, wherein:
the conductive terminal is a first conductive terminal and the surface of the dielectric material is a first surface that opposes a second surface of the dielectric material,
the first conductive terminal is on the first surface of the dielectric material and coupled to the end portion of the first winding, and
the apparatus further comprises a second conductive terminal on the second surface of the dielectric material and coupled to the end portion of the second winding.

12. The apparatus of claim 9, wherein:
the dielectric material comprises a laminate substrate having a plurality of layers,
the first winding resides on or within a first of the plurality of layers, and
the second winding resides on or within a second of the plurality of layers.

13. The apparatus of claim 12, wherein the plurality of layers of the dielectric material comprises respective layers of one of a prepreg material, a buildup film, or a polyimide material.

14. The apparatus of claim 9, wherein each of the first and second windings has a spiral shape surrounding the central region.

15. A method comprising:
forming a cavity in a multi-layer substrate of a leadframe, in which the cavity extends from a first substrate surface of the leadframe into the multi-layer substrate to define a cavity floor spaced from the first substrate surface by a cavity sidewall, at least one conductive terminal being on the cavity floor;
placing an inductor module in the cavity, in which the inductor module includes a conductor embedded within a dielectric substrate between spaced apart first and second inductor terminals of the inductor module;
coupling at least one of the first and second inductor terminals to the at least one conductive terminal on the cavity floor; and
encapsulating the inductor module and at least a portion of the leadframe with a mold compound.

16. The method of claim 15, wherein:
prior to forming the cavity, the multi-layer substrate includes one or more copper layers, and
forming the cavity includes etching the one or more copper layers to form the at least one conductive terminal on the cavity floor.

17. The method of claim 15, wherein the multi-layer substrate includes an arrangement of conductive leadframe terminals on a respective area of the first substrate surface adjacent the cavity, and the method further comprises:
mounting a die to the respective area of the first substrate surface, in which the die includes bond pads; and
coupling the bond pads to respective conductive leadframe terminals, and the mold compound further encapsulating the die.

18. The method of claim 15, wherein at least a portion of the dielectric substrate of the inductor module has a magnetic permeability that is greater than the mold compound.

19. The method of claim 18, wherein the inductor module includes a multi-layer inductor comprising:
a first winding of a conductive material having a radially inner edge;
a second winding of the conductive material spaced axially from and over the first winding, in which the second winding is coupled to the first winding through a via extending in the dielectric substrate, the second winding has a radially inner edge substantially coaxial with the radially inner edge of the first winding to define a central region extending coaxially through the first and second windings, and the dielectric substrate encapsulates the first and second windings; and
a central core of a magnetic mold compound within at least a portion of the central region.

20. The method of claim 19, wherein:
the dielectric substrate includes a plurality of layers,
the first winding resides on or within a first of the plurality of layers, and
the second winding resides on or within a second of the plurality of layers.

21. The method of claim 20, wherein the plurality of layers of the dielectric substrate comprises one of a prepreg material, a buildup film, or a polyimide material.

22. The method of claim 19, wherein each of the first and second windings has a spiral shape surrounding the central region.
